(19) United States
(12) Patent Application Publication
(10) Pub. No.: US 2002/0072146 A1
(43) Pub. Date: Jun. 13, 2002

(54) Light control device, method for driving same and pickup device using the light control device

(76) Inventor: Hiroo Shoji, Tokyo (JP)

Correspondence Address: David R. Metzger, SONNENSCHEIN NATH & ROSENTHAL, Wacker Drive Station, Sears Tower, P.O. Box #061080, Chicago, IL, 60606-1080, US

(21) Appl. No.: 09/974,333

(22) Filed: Oct. 10, 2001

(30) Foreign Application Priority Data
Oct. 10, 2000 (JP) P2000-309367

(51) Int. Cl. H01L 21/48; H01L 23/02; H01L 23/34

(52) U.S. Cl. 438/106; 257/678; 257/712

(57) ABSTRACT

A transporting method, a packaging method, and a packaging kit for semiconductor devices protect semiconductor devices, such as solid-state image sensing devices, from characteristic degradation thereof caused by exposure to cosmic rays during transport by air. The semiconductor devices are air-transported while being maintained warm at a predetermined temperature at which characteristic degradation attributable to the exposure to cosmic rays can be restrained.

### BACKGROUND OF THE INVENTION

1. Field of the Invention

The present invention relates to a transporting method, particularly a transporting method applied to air transport, for semiconductor devices, such as solid-state image sensing devices, and a packaging method and a packaging kit for semiconductor devices.

2. Description of the Related Art

White defects at dark signals are one of the image defects in a solid-state image sensing device, such as a CCD solid-state image sensing device. The white defects are classified into two types.

The white defects of the first defect type are minor defects based on a defect level caused by a very small amount of an impurity, such as a heavy metal, mixed in during a semiconductor manufacturing process. This type of defects is known by the name of “initial white defects.” The initial white defects are a most important issue in a process that determines a yield; however, this type of defects can be removed by screening based on measurement prior to shipment of finished products.

On the other hand, the defects of the second type are image defects known as “subsequent white defects” that usually develop in nondefectives after the completion of assembly, measurement, and screening. The subsequent white defects are regarded as an extremely serious problem because this type of defects takes place in the products shipped as nondefectives.

The subsequent white defects in solid-state image sensing devices are known to be attributable to the alpha rays in a packaging material and exotic cosmic rays. Companies have taken thorough measures against the alpha rays in packaging materials, and adopted materials having as low an alpha ray density as possible for various types of packaging materials and also the materials used in a wafer process.

If a sealing glass material used for a package contains radioactive elements, such as uranium (U) or thorium (Th), then uranium (U) or thorium (Th) alpha-decays, producing alpha rays. When the alpha rays enter a solid-state image sensing device, the loss of the energy thereof is classified into an electronic energy loss and a nuclear energy loss.

In the course of the electronic energy loss, pairs of holes and electrons are produced. The consequent charges cause pixels to generate instantaneous dark current spikes in the case of a CCD solid-state image sensing device. In a semiconductor memory, the charges from the electronic energy loss give rise to malfunctions of the memory. This is known as a “soft error.” Meanwhile, the nuclear energy loss causes a crystal defect in silicon, and the crystal defect causes a defect level to be developed and fixed in the silicon, resulting in permanent damage. This leads to an increase in the dark current at pixels and transferring sections in the CCD solid-state image sensing device.

How cosmic rays cause the white defects will now be described. Similarly to alpha rays, cosmic rays are also responsible for the white defects. The amount of cosmic rays depends on altitude, and the intensity of cosmic rays increases as the altitude increases. For example, the density of cosmic rays at an aircraft flight altitude of 10,000 meters is approximately not less than one hundred times that on the ground level. For this reason, the subsequent white defects developed in CCD solid-state image sensing devices due to the exposure to cosmic rays during flight are regarded as a serious problem.

Cosmic rays attenuate as they pass through a material; however, the energy of cosmic rays is high (unit: GeV). Typical transport packaging uses cardboard boxes, duralumin trunks, or the like. These packaging materials, however, are hardly effective for preventing white defects from taking place because cosmic rays scarcely attenuate when they pass therethrough. Hence, it has been impossible for standard packaging means to prevent the occurrence of white defects attributable to cosmic rays.

### SUMMARY OF THE INVENTION

In view of the prior art described above, it is an object of the present invention to provide a transporting method, a packaging method, and a packaging kit for semiconductor devices that protect the semiconductor devices from degradation of the characteristics thereof caused by exposure to cosmic rays during transport by air.

According to one aspect of the present invention, there is provided a transporting method for transporting semiconductor devices by air, wherein the semiconductor devices are air-transported while being maintained at a predetermined temperature that makes it possible to restrain characteristic deterioration caused by exposure to cosmic rays.

This arrangement makes it possible to control the occurrence of characteristic deterioration due to exposure to cosmic rays by warming semiconductor devices at a predetermined temperature during air transport.

More specifically, maintaining semiconductor devices at a predetermined high temperature minimizes the possibility of the semiconductor devices developing dot defects even if they are exposed to cosmic rays. Alternatively, the dot defects that have taken place due to exposure to cosmic rays may be improved by maintaining a predetermined high temperature so as to provide annealing effect.

Preferably, a heating unit is used for maintaining the semiconductor devices warm.

Preferably, the heating unit is formed of a laminate having a plurality of heating members.

Preferably, the heating unit has an oxygen-permeable control layer.

Preferably, the heating unit is capable of maintaining the predetermined temperature during air transport.

Preferably, the predetermined temperature is 40° C. or higher.

Preferably, the semiconductor devices are image pickup devices.

According to another aspect of the present invention, there is provided a packaging method for semiconductor devices, wherein a heating unit heated to a predetermined temperature at which characteristic deterioration of a semiconductor device caused by exposure to cosmic rays can be restrained is disposed on a container accommodating the semiconductor devices, and the container is packaged by being accommodated together with the heating unit in a container box.

With this arrangement, the semiconductor device is packaged together with the heating unit heated to a predetermined temperature at which characteristic deterioration of semiconductor devices can be restrained. Hence, the characteristic deterioration of the semiconductor devices can be controlled even if the semiconductor device is exposed to cosmic rays during air transport. As the heating unit, a portable handwarmer is used to ensure safety during air transport.

According to yet another aspect of the present invention, there is provided a packaging kit having a container box that accommodates a container holding semiconductor devices therein and a heating unit heated to a predetermined temperature at which characteristic deterioration of the semiconductor devices caused by exposure to cosmic rays can be restrained.

With this arrangement, the semiconductor devices are packaged in the packaging box together with the heating unit heated to a predetermined temperature at which characteristic deterioration of semiconductor devices can be restrained. Hence, the characteristic deterioration of the semiconductor devices can be controlled even if the semiconductor devices are exposed to cosmic rays during air transport.

### BRIEF DESCRIPTION OF THE DRAWINGS

FIG. 1A through FIG. 1C are process diagrams (Part 1) illustrating an embodiment of a package of products suited to the transporting method for semiconductor devices in accordance with the present invention, and FIG. 1D and FIG. 1E are process diagrams (Part 2) illustrating the embodiment of the package of products suited to the transporting method for semiconductor devices in accordance with the present invention;

FIG. 2 is a process diagram (Part 3) illustrating the embodiment of the package of products suited to the transporting method for semiconductor devices in accordance with the present invention;

FIG. 3A is a sectional view illustrating an example of a portable handwarmer in accordance with the present invention, and FIG. 3B is a perspective view of one tabular portable handwarmer member of the portable handwarmer;

FIG. 4 is a construction diagram showing another embodiment of the package for products suited to the transporting method for semiconductor devices in accordance with the present invention;

FIG. 5 is a sectional view illustrating another example of the portable handwarmer in accordance with the present invention;

FIG. 6 is a construction diagram showing yet another embodiment of the package for products suited to the transporting method for semiconductor devices in accordance with the present invention;

FIG. 7 is a sectional view illustrating yet another example of the portable handwarmer in accordance with the present invention; and

FIG. 8 is a construction diagram showing still another embodiment of the package for products suited to the transporting method for semiconductor devices in accordance with the present invention.

### DESCRIPTION OF THE PREFERRED EMBODIMENTS

Subsequent white defects in semiconductor devices, such as CCD solid-state image sensing devices and CMOS sensors, take place in proportion to the total amount of dosage of cosmic rays. As mentioned above, the density of cosmic rays depends on altitude, and when an airplane is flying at an air height of 10,000 meters, the cosmic ray density is approximately one hundred times or more higher than that on the ground level. Therefore, when semiconductor devices, such as solid-state image sensing devices, are transported by air from Japan to Europe or the United States, crystal defects, which turn into subsequent white defects in the case of solid-state image sensing devices, will be dominant during air transport in which a high cosmic ray density is unavoidable.

For instance, when solid-state image sensing devices are shipped out of a plant, in the whole period of time from the shipment from the plant to the arrival at a local distributor or the like, the dosage of cosmic rays is the largest during the flight at the altitude of 10,000 meters rather than at the time of custom clearance or during domestic storage, or in other words, about a few days on the average following the shipment from a plant.

It has been known that the subsequent white defects in solid-state image sensing devices improve or disappear when annealed at a certain temperature.

In the transporting method for semiconductor devices according to the embodiment, to transport semiconductor devices (e.g., solid-state image sensing devices) by air, the semiconductor devices are maintained at a predetermined temperature at which characteristic deterioration due to exposure to cosmic rays during the air transport can be controlled. During air transport of, for example, solid-state image sensing devices, the devices are maintained at a temperature at which the occurrence of subsequent white defects can be restrained.

During the flight, heating means is subjected to considerably stricter restraints than on the ground. For this reason, the use of means based on regular combustion or Joule heat generated by electricity is not allowed from the viewpoint of safety in aircraft.

In the embodiment, therefore, a portable handwarmer is used as a heating unit for keeping semiconductor devices warm during the air transport thereof.

Regular portable handwarmers last only about twenty hours, while the portable handwarmer used in the embodiment lasts sufficiently long for air transport.

The portable handwarmer contains, as its heat generating compositions, i.e., handwarmer fillers, metal powder, salts, and water, and may further contain a water retention agent, a reaction accelerator, and the like.

The metal powder is preferably, for example, iron, aluminum, zinc, or copper powder. Iron powder is preferable from the viewpoint of economy, reactivity, and safety.

Salts may be, for example, chlorides of alkali metals, such as sodium chloride or potassium chloride, or chlorides of alkali earth metal, such as calcium chloride or magnesium chloride.

The water retention agent may be, for example, wood flour, pulp, calcium silicate, silica gel, silica-based porous material, alumina, or water-absorbing polymer.

The reaction accelerator may be, for example, activated carbon, carbon black, or graphite.

The heat generation by the portable handwarmer is based on a reaction represented by the following formula:

Fe+0.75 O₂ +1.5 H₂O→Fe (OH)₃+96.5 Kcal

Accordingly, oxygen and water vapor are involved in the reaction, and oxygen dominantly diffuses because moisture is sealed in the handwarmer. It is important to control the diffusion of oxygen in the vertical direction, i.e., in the direction of the thickness of the heating unit because a typical portable handwarmer is tabular. This means that successful control of the diffusion of oxygen in the vertical direction is important to ensure prolonged heat generation.

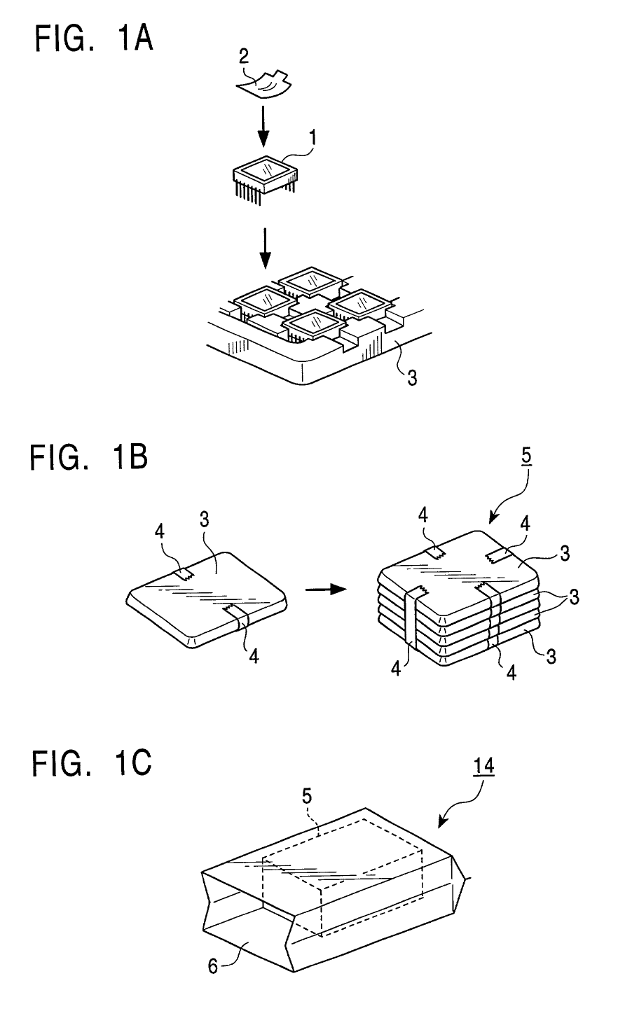

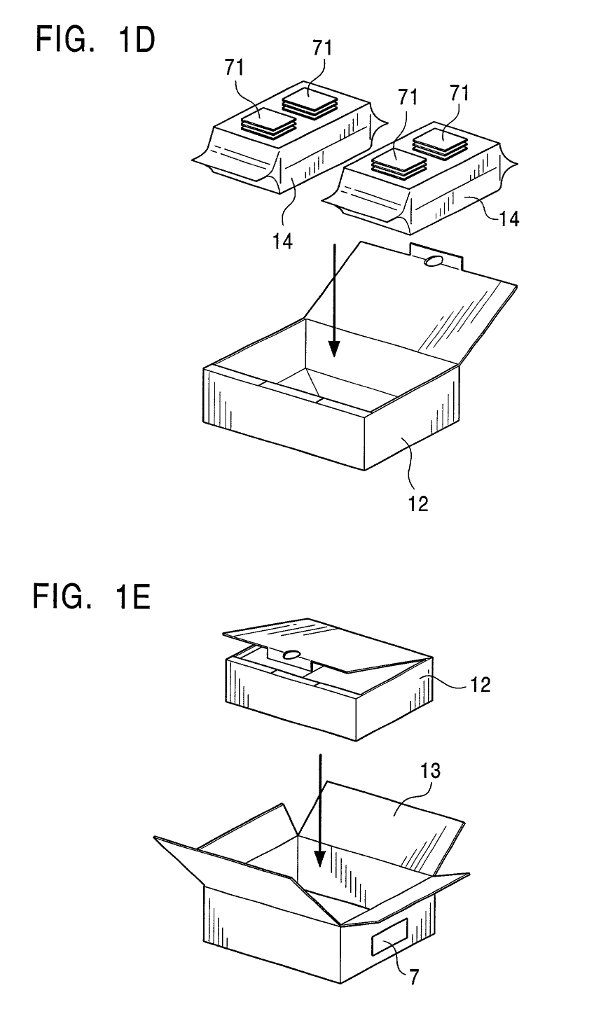

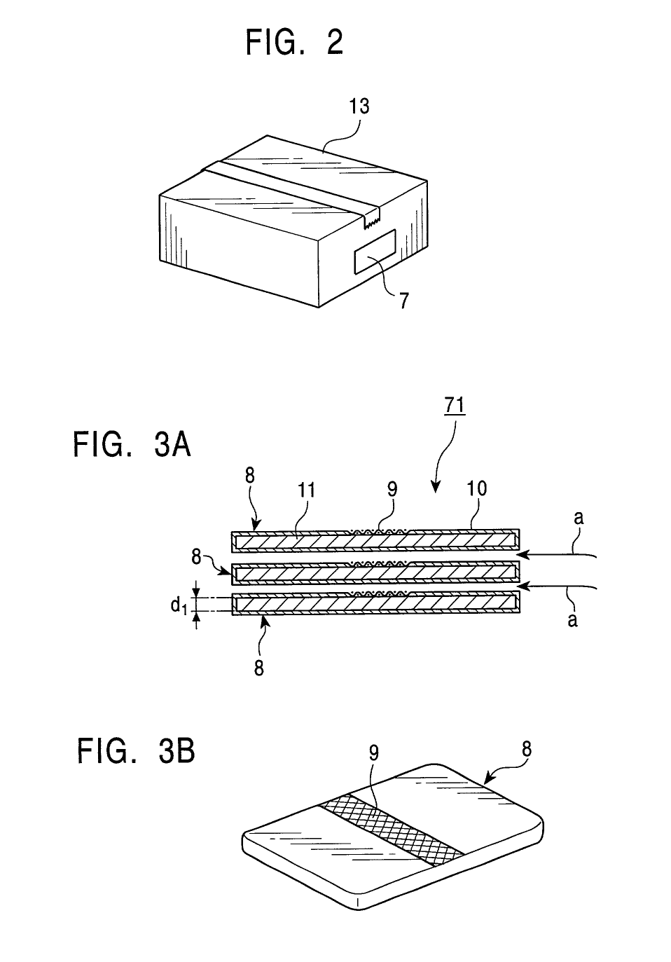

FIG. 1 and FIG. 2 show an embodiment of a product packaging specification suited to the transporting method for semiconductor devices in accordance with the present invention, the embodiment being applied to the packaging of solid-state image sensing devices.

In this embodiment, as shown in FIG. 1A, a plurality of (e.g., fifty) solid-state image sensing devices 1 with their image sensing surfaces protected with protective tapes 2 are placed in a product accommodating tray 3. The product accommodating tray 3 is packaged and fastened with, for example, vinyl tapes 4.

Then, as shown in FIG. 1B, a plurality of (e.g., five) the packaged trays 3 are stacked in tiers, and combined into one piece with, for example, the vinyl tapes 4, so as to form a tray laminate 5.

Subsequently, as shown in FIG. 1C, the tray laminate 5 formed of a plurality of trays 3 combined into one piece is accommodated in a sealing bag 6 to constitute a container 14 for solid-state image sensing devices.

In this embodiment, the tray laminate 5 is accommodated in, for example, an aluminum laminate bag 6, and the aluminum laminate bag 6 is thermally sealed thereby to form the aluminum laminate package serving as the container 14.

Meanwhile, a portable handwarmer functioning as a heat generating source is prepared. The portable handwarmer is required to generate heat of a temperature that makes it possible to restrain the occurrence of dot defects attributable to exposure to cosmic rays. The temperature ranges, for example, from 40° C. to a degree that will not cause a hazard during transport (e.g., 70° C. or below). As mentioned above, a portable handwarmer laminate 71 is required to be able to generate heat for an extended time, so that the portable handwarmer laminate 71 must be constructed to permit oxygen diffusion control.

In this embodiment, as shown in FIG. 3, the portable handwarmer laminate (a laminated handwarmer) 71 is constructed by a plurality of (three in this embodiment) tabular portable handwarmers 8 stacked in three layers to enable oxygen diffusion control to be effected. Each tabular portable handwarmer 8 is formed by charging a handwarmer filler, i.e., the heat generating composition, 11 in an inner bag 10 made of a sheet having a breathable portion 9 only in a predetermined area on one surface thereof, while the rest thereof is made non-breathable, as shown in FIG. 3B. The tabular portable handwarmers 8 are stacked in three layers such that the breathable portions 9 face upward, thus constructing the portable handwarmer laminate 71 (see FIG. 3A). In the portable handwarmer laminate 71, the three tabular portable handwarmers 8 can be stacked. Hence, air “a” enters the lower two portable handwarmers 8 through the gaps between tiered portable handwarmers 8, so that the diffusion of oxygen, which contributes to exothermic reaction, to the handwarmer filler 11 will be restrained more than the diffusion to the portable handwarmer 8 of the topmost layer, thus permitting prolonged heat generation.

For the portable handwarmer laminate 71 to maintain a temperature of, for example, 40° C. or above, for 72 hours or longer, the area ratio or a porous open area ratio of the breathable portion 9 to the tabular area of the tabular portable handwarmer 8 should be set to 20% or less, preferably to 5% to 15%. If the ratio is smaller than 5%, then poor air permeability results, making it difficult to reach the predetermined temperature 40° C. Conversely, if the ratio is larger than 15%, then it will be difficult to maintain the temperature within the required range for 72 hours or longer.

For the tabular portable handwarmers 8, commercially available tabular heating elements may alternatively be used.

Then, as shown in FIG. 1D, the portable handwarmer laminate formed of the three tabular portable handwarmers 8 stacked in three layers is disposed on one aluminum laminate package 14 holding the tray laminate 5. In this embodiment, the portable handwarmer laminates 71 are disposed at a plurality of places on the top and bottom surfaces of the one aluminum laminate package 14, e.g., four places (two places each on the top surface and the bottom surface, respectively).

Furthermore, the aluminum laminate package 14 with the portable handwarmer laminates 71 attached thereto is accommodated in, for example, an inner box 12 made of corrugated cardboard. In this embodiment, two aluminum laminate packages 14 are accommodated in the inner box 12.

Lastly, as shown in FIG. 1E, the inner box 12 is further placed in, for example, an outer box 13 made of corrugated cardboard. FIG. 2 shows a completed package. Reference numeral 7 denotes a label attached to the outer box 13.

According to the embodiment, the solid-state image sensing devices 1 are packaged together with the portable handwarmer laminates 71 to keep the solid-state image sensing devices 1 at a predetermined temperature by the portable handwarmer laminates 71 during air transport. It is therefore possible to control the occurrence of subsequent white defects caused by exposure to cosmic rays during air transport. More specifically, the solid-state image sensing devices are maintained at a temperature of 40° C. or above, thus minimizing the possibility of developing dot defects despite the exposure to cosmic rays. Moreover, even if dot defects take place due to the exposure to cosmic rays, the devices are maintained at a temperature of 40° C. or above, meaning that the devices are held under an annealing condition to permit crystal recovery.

First Operative Example

A portable handwarmer laminate 71 formed of three layers of tabular portable handwarmers 8 was prepared. Each of the tabular portable handwarmers 8 measures 120 mm long×90 mm wide×4 mm thick and includes a 50-gram handwarmer filler, an area portion of a breathable portion 9 at the center of one surface being about 9% or about 13%. The portable handwarmer laminates 71 were disposed at a total of eight places of two aluminum laminate packages 14 (four on each package) at the top and bottom surfaces thereof. Thus, when a total of twenty-four tabular portable handwarmers 8 were used for the package, it was possible to maintain the temperature at 40° C. or above for 72 hours or longer.

The handwarmer fillers, i.e., the compositions of the heat generating member, used for the example are as shown below:

Iron powder: Content 50 to 60 wt %

Water: Content 15 to 25 wt %

Wood flour: Fineness 10 mesh or smaller

Activated carbon: Woody activated carbon

Vermiculite

Salt

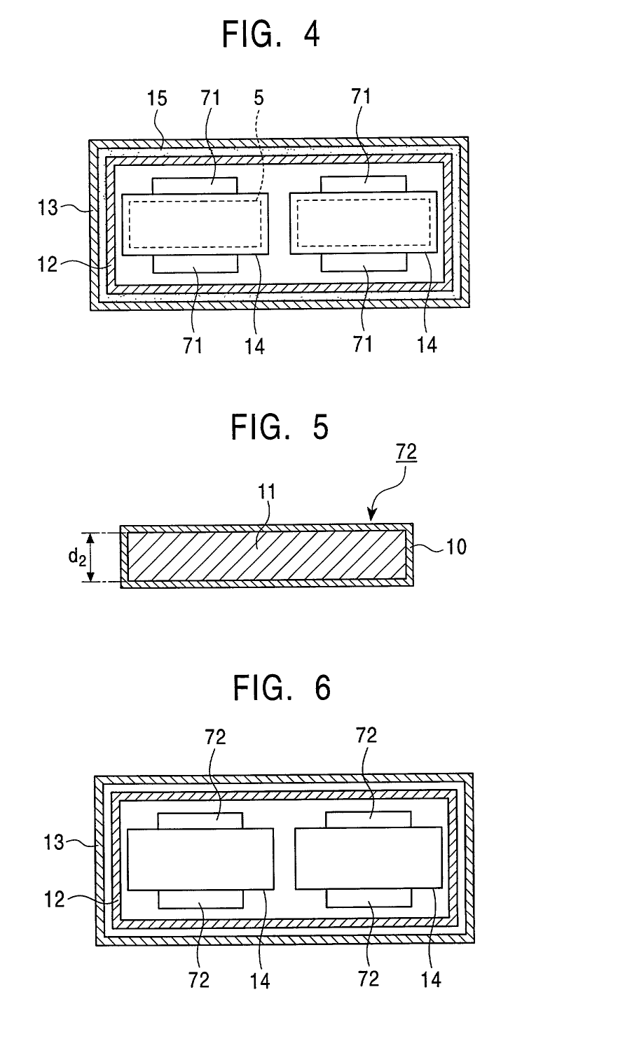

FIG. 4 shows another embodiment of the product packaging specification suited to the transporting method for semiconductor devices in accordance with the present invention. The embodiment illustrates another case where the present invention has been applied to the packaging of solid-state image sensing devices.

In this embodiment, a plurality of stacked layers of portable handwarmer laminates 71, for example, are inserted into an inner box 12 together with aluminum laminate packages 14 in which tray laminates 5 have been sealed. The inner box 12 is inserted in an outer box 13, then a ventilation control member 15 is disposed between the inner box 12 and the outer box 13 such that it surrounds the inner box 12, thereby completing the packaging.

For the ventilation control member 15, a continuous foam type urethane cushion or the like may be used. The continuous foam type urethane cushion also works to lessen external shocks.

For the portable handwarmer laminates 71, the heating element laminates having the local breathable portions 9 as in the case of the ones shown in FIG. 3B, or heating element laminates with their inner bags 8 (shown in FIG. 3B) provided with breathable portions over the entire surfaces.

According to this embodiment, the ventilation control member 15 is disposed between the outer box 13 and the inner box 12 accommodating the aluminum laminate packages 14 and the portable handwarmer laminates 71 to complete packaging thereby to make it possible to maintain heat generation at 40° C. or above by the portable handwarmer laminates 71 for an extended time during air transport. This arrangement enables the occurrence of subsequent white defects caused by the exposure to cosmic rays during air transport to be restrained.

Second Operative Example

When a continuous foam type urethane cushion was used as a ventilation control member 15, and portable handwarmer laminates 71, each being formed of four layers of the tabular portable handwarmers 8 in the first operative example, were disposed at three places of each of two aluminum laminate packages 14 (a total of six places, meaning that a total of twenty-four tabular portable handwarmers 8 were used) to effect packaging, it was possible to maintain a temperature of 40° C. or above for seven days or longer. The incidence of subsequent white defects can be cut by half as compared with a conventional package by using the thermal packaging to transport CCD solid-state image sensing devices from a plant to London via Narita Airport.

FIG. 5 and FIG. 6 show another embodiment of the product packaging specification suited to the transporting method for semiconductor devices in accordance with the present invention, the embodiment being applied to the packaging of solid-state image sensing devices.

In this embodiment, as illustrated in FIG. 5, for the heating elements that control the diffusion of oxygen to permit extended heat generation, portable handwarmers 72 are used. Each of the portable handwarmer 72 has a filler 11 of an amount that makes it possible to maintain a predetermined temperature (e.g., 40° C. or above) during a period of air transport and/or has a thickness d₂ that allows a predetermined temperature (e.g., 40° C. or above) to be maintained during a period of air transport.

More specifically, as illustrated in FIG. 6, together with aluminum laminate packages 14 in which tray laminates 5 have been sealed, the single-layer portable handwarmers 72 are inserted in an inner box 12. Each of the portable handwarmers 72 has several times the number of fillers 11, as compared with the tabular portable handwarmer 8 and a thickness d₂ of each of the fillers 11 is several times larger than the thickness d₁ of the handwarmer 8 (see FIG. 3). The inner box 12 is further inserted in an outer box 13 to complete packaging.

One or plural portable handwarmers 72 may be disposed on each aluminum laminate package 14.

According to the embodiment, the portable handwarmers 72 having the increased quantity of the filler 11 and the increased thickness d₂ are used for packaging, thereby making it possible to accomplish extended heat generation to maintain a temperature of 40° C. or above by the portable handwarmers 72 during air transport. Thus, the occurrence of subsequent white defects caused by the exposure to cosmic rays during air transport can be controlled.

Third Operative Example

In this example, a single-layer portable handwarmer 72 having a five-fold or greater (e.g., eleven-fold) quantity of the filler 11 than that of the tabular portable handwarmer 8 in the first operative example and a thickness d₂ that is triple the thickness d₁ or greater (e.g., triple) of the portable handwarmer 8 was disposed on each aluminum laminate package 14 to package CCD solid-state image sensing devices. The example made it possible to achieve the extended heating similar to that in the second operative example during the air transport over the same distance as that in the second operative example. Thus, the incidence of subsequent white defects can be cut by half, as compared with conventional packages.

Fourth Operative Example

A single-layer heating element was used, that measures 220 mm long×160 mm wide×8 mm thick (the thickness of a filler 11 is double the thickness d, of the handwarmer 8). The quantity (size) of the filler 11 was 7.3 times that of the aforesaid tabular portable handwarmer 8, and an area portion of a breathable portion 9 at the center of one surface was set to about 10% (area of the breathable portion 9:220 mm×20 mm). A total of four heating elements were disposed on two aluminum laminate packages 14 (one each on the top surface and the bottom surface, respectively, of each package). With this arrangement, it was possible to maintain a temperature at 40° C. or above for 120 hours or longer.

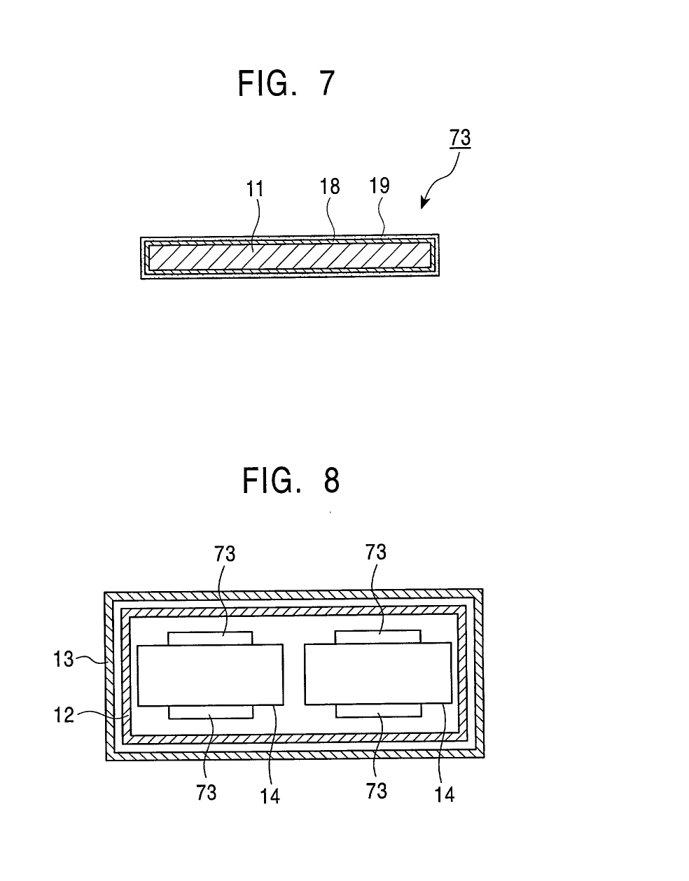

FIG. 7 and FIG. 8 show still another embodiment of the product packaging specification suited to the transporting method for semiconductor devices in accordance with the present invention, the embodiment being applied to the packaging of solid-state image sensing devices.

A heating element used in this embodiment has an oxygen control layer in the bag accommodating a filler.

More specifically, according to the embodiment, a single-layer portable handwarmer 73 is used, in which an oxygen permeable control layer 19 for letting oxygen to pass therethrough is formed around an inner bag 18 that accommodates a filler 11 and has a breathable portion. The portable handwarmers 73 are inserted in an inner box 12 together with aluminum laminate packages 14 in which tray laminates 5 have been sealed, then the inner box 12 is further inserted in an outer box 13 to complete packaging.

The oxygen permeable control layer 19 may be formed of, for example, a CiN film, a diamond-like carbon film or the like. The inner bag 18 may be formed to be either entirely or partly breathable. The oxygen permeable control layer 19 may be formed on either the entire surface or only one surface of the inner bag 18.

Furthermore, a ventilation control member, e.g., the continuous foam type urethane cushion 15 shown in FIG. 4 discussed above, may be also added between the inner box 12 and the outer box 13.

According to the embodiment, extended heat generation for maintaining a temperature of 40° C. or above can be achieved by the portable handwarmers 73 during air transport. Thus, the occurrence of subsequent white defects caused by the exposure to cosmic rays during air transport can be controlled.

Fifth Operative Example

A single-layer portable handwarmer 73 in this operative example has an oxygen permeable control layer 19 exhibiting an oxygen permeability that is one third of that in the tabular portable handwarmer in the first operative example was formed around the inner bag of the tabular portable handwarmer in the first operative example. By disposing a total of eight single-layer portable handwarmers 73 on two aluminum laminate packages (two each on the top surface and the bottom surface, respectively, of each package) to package CCD solid-state image sensing devices, it was possible to achieve the extended heating similar to that in the second operative example during the air transport over the same distance as that in the second operative example. Thus, the incidence of subsequent white defects can be cut by half, as compared with conventional packages.

First Comparative Example

In this comparative example, CCD solid-state image sensing devices were packaged in the same manner as in the first operative example except that portable handwarmer laminates, each laminate including two layers of the tabular portable handwarmers 8 in the first operative example, were disposed at six locations of each of two aluminum laminate packages 14 (a total of twenty-four tabular heating elements). According to the comparative example, the heating for maintaining a temperature of 40° C. or above lasted for about thirty-six hours, and the effect for reducing the incidence of subsequent white defects during air transport was not observed.

Second Comparative Example

In this comparative example, CCD solid-state image sensing devices were packaged in the same manner as in the second operative example except that the single-layer tabular portable handwarmers 8 in the first operative example were disposed at four locations of each of two aluminum laminate packages 14 (a total of eight tabular portable handwarmers 8), and an air cap permitting no air circulation was disposed between the aluminum laminate packages 14 and the inner boxes 12. According to this example, the heating to maintain a temperature of 40° C. or above lasted for about thirty-two hours during the air transport along the same route as that in the second operative example, and the effect for reducing the incidence of subsequent white defects during air transport was not observed.

In the above operative examples, the present invention has been applied to the packaging and air transport of CCD solid-state image sensing devices. The present invention, however, can be also applied to the packaging and air transport of other types of solid-state image sensing devices, such as CMOS sensors, and semiconductor devices, such as semiconductor memories.

Thus, according to the transporting method for semiconductor devices in accordance with the present invention, in the air transport of semiconductor devices, such as solid-state image sensing devices, the occurrence of crystal defects attributable to the exposure to cosmic rays can be restrained, so that characteristic degradation during air transport can be accordingly restrained. If the semiconductor devices to be air-transported are solid-state image sensing devices, the occurrence of image defects, namely, subsequent white defects, caused by the exposure to cosmic rays can be restrained.

A predetermined temperature that is 40° C. and above and does not lead to any hazardous conditions can be maintained for a long time when a portable handwarmer unit is constructed by stacking a plurality of portable handwarmers, by providing a filler bag thereof with an oxygen-permeable control layer, by providing a sufficient quantity of fillers for maintaining a predetermined temperature during air transport, or by providing a filler that is sufficiently thick for maintaining a predetermined temperature during air transport.

The packaging method in accordance with the present invention makes it possible to control the occurrence of crystal defects in semiconductor devices attributable to the exposure to cosmic rays can be restrained. Hence, the packaging method is ideally suited to packaging for air-transporting semiconductor devices, including solid-state image sensing devices.

The packaging kit in accordance with the present invention makes it possible to control the characteristic deterioration of semiconductor devices even if the semiconductor devices are exposed to cosmic rays during air transport.

What is claimed is:

1. A transporting method for transporting semiconductor devices by air, wherein
semiconductor devices are air-transported while maintaining the semiconductor devices at a predetermined temperature at which characteristic deterioration caused by exposure to cosmic rays can be restrained.

2. A transporting method for semiconductor devices according to claim 1, wherein a heating unit is used for maintaining the semiconductor devices warm.

3. A transporting method for semiconductor devices according to claim 2, wherein the heating unit is formed of a laminate having a plurality of heating members.

4. A transporting method for semiconductor devices according to claim 2, wherein the heating unit has an oxygen-permeable control layer.

5. A transporting method for semiconductor devices according to claim 2, wherein the heating unit is capable of maintaining the predetermined temperature during air transport.

6. A transporting method for semiconductor devices according to claim 1, wherein the predetermined temperature is 40° C. or higher.

7. A transporting method for semiconductor devices according to claim 1, wherein the semiconductor devices are image pickup devices.

8. A packaging method for a semiconductor device, wherein a heating unit heated to a predetermined temperature at which characteristic deterioration of semiconductor devices caused by exposure to cosmic rays can be restrained is disposed on a container accommodating semiconductor devices, and
the container is packaged by being accommodated together with the heating unit in a container box.

9. A packaging kit having a container box that accommodates a container holding a semiconductor device therein and a heating unit heated to a predetermined temperature at which characteristic deterioration of semiconductor devices caused by exposure to cosmic rays can be restrained.
